(19) United States
(12) Patent Application Publication
(10) Pub. No.: US 2014/0239490 A1
(43) Pub. Date: Aug. 28, 2014

(54) PACKAGING SUBSTRATE AND FABRICATION METHOD THEREOF

(71) Applicant: UNIMICRON TECHNOLOGY CORPORATION, Taoyuan (TW)

(72) Inventor: Ying-Tung Wang, Taoyuan (TW)

(73) Assignee: UNIMICRON TECHNOLOGY CORPORATION, Taoyuan (TW)

(21) Appl. No.: 13/777,097

(22) Filed: Feb. 26, 2013

(51) Int. Cl. H01L 23/498; H01L 21/768

(52) U.S. Cl. CPC H01L 23/49811; H01L 21/76885
USPC 257/737; 438/613

(57) ABSTRACT

A packaging substrate and a fabrication method thereof are disclosed. The packaging substrate includes: a substrate body having a plurality of first and second conductive pads formed on a surface thereof; a first insulating layer formed on the surface of the substrate body and having a plurality of first and second openings for respectively exposing the first and second conductive pads; a conductive layer formed on the first and second conductive pads and the first insulating layer around peripheries of the first and second conductive pads; a plurality of first and second conductive bumps formed on the conductive layer on the first and second conductive pads, respectively; a solder layer formed on the second conductive bumps; and a plurality of conductive posts formed on the first conductive bumps and having a width different from that of the first conductive bumps. The invention improves the fabrication efficiency.

### BACKGROUND OF THE INVENTION

1. Field of the Invention

The present invention relates to packaging substrates and fabrication methods thereof, and more particularly, to a packaging substrate having conductive posts and a fabrication method thereof.

2. Description of Related Art

Along with the miniaturization of electronic products, printed circuit boards have less area available for mounting package structures. Accordingly, 3D-stack technologies have been developed to form 3D-stack structures. In such a 3D-stack structure, a plurality of conductive bumps or posts are formed on a package structure so as for another package structure to be stacked thereon, thereby forming a package on package (POP) structure to meet the requirements of small bonding area and high element density.

FIGS. 1A to 1J are schematic cross-sectional views showing a conventional packaging substrate used for a stack package structure and a fabrication method thereof.

Referring to FIG. 1A, a substrate body 10 having opposite first and second surfaces 10a, 10b is provided. The first surface 10a has a plurality of first conductive pads 111 and a plurality of second conductive pads 112, and the second surface 10b has a plurality of third conductive pads 113. A first insulating layer 12a is formed on the first surface 10a and has a plurality of first openings 121 for exposing the first conductive pads 111 and a plurality of second openings 122 for exposing the second conductive pads 112. A second insulating layer 12b is formed on the second surface 10b and has a plurality of third openings 123 for exposing the third conductive pads 113.

Referring to FIG. 1B, a first conductive layer 13a is formed on the first insulating layer 12a, the first conductive pads 111 and the second conductive pads 112 and a second conductive layer 13b is formed on the second insulating layer 12b and the third conductive pads 113.

Referring to FIG. 1C, a first resist layer 14a is formed on the first conductive layer 13a and has a plurality of fourth openings 141 for exposing the first openings 121 of the first insulating layer 12a and a plurality of fifth openings 142 for exposing the second openings 122 of the first insulating layer 12a. Further, a third resist layer 14b is formed on the second conductive layer 13b.

Referring to FIG. 1D, a plurality of first conductive bumps 151 are formed in the fourth openings 141 of the first resist layer 14 and a plurality of second conductive bumps 152 are formed in the fifth openings 142 of the first resist layer 14.

Referring to FIG. 1E, a second resist layer 17 is formed on the first resist layer 14a, the first conductive bumps 151 and the second conductive bumps 152 and has a plurality of sixth openings 170 for exposing the second conductive bumps 152.

Referring to FIG. 1F, a solder layer 16 is formed on the second conductive bumps 152.

Referring to FIG. 1G, the second resist layer 17, the first resist layer 14a and the third resist layer 14b are removed.

Referring to FIG. 1H, a fourth resist layer 19a is formed on the first conductive layer 13a and the solder layer 16 and has a plurality of seventh openings 190 corresponding in position to the first conductive bumps 151 and a fifth resist layer 19b is formed on the second conductive layer 13b.

Referring to FIG. 1I, a plurality of conductive posts 18 are formed on the first conductive bumps 151.

Referring to FIG. 1J, the fourth resist layer 19a and the first conductive layer 13a covered by the fourth resist layer 19a, and the fifth resist layer 19b and the second conductive layer 13b covered by the fifth resist layer 19b are removed.

However, the above-described method requires three patterning processes for forming the resist layers and two removing processes for removing the resist layers. As such, the fabrication process is quite complicated, time-consuming and costly, thus resulting in low competitiveness.

Therefore, there is a need to provide a packaging substrate and a fabrication method thereof so as to overcome the above-described drawbacks.

### SUMMARY OF THE INVENTION

In view of the above-described drawbacks, the present invention provides a semiconductor substrate, which comprises: a substrate body having a first surface with a plurality of first conductive pads and a plurality of second conductive pads and a second surface opposite to the first surface; a first insulating layer formed on the first surface of the substrate body and having a plurality of first openings for exposing the first conductive pads and a plurality of second openings for exposing the second conductive pads; a conductive layer formed on the first conductive pads, the second conductive pads and the first insulating layer around peripheries of the first and second conductive pads; a plurality of first conductive bumps formed on the conductive layer on the first conductive pads and a plurality of second conductive bumps formed on the conductive layer on the second conductive pads; a solder layer formed on the second conductive bumps; and a plurality of conductive posts formed on the first conductive bumps and having a width different from that of the first conductive bumps.

The present invention provides another packaging substrate, which comprises: a substrate body having a first surface with a plurality of first conductive pads and a plurality of second conductive pads and a second surface opposite to the first surface; a first insulating layer formed on the first surface of the substrate body and having a plurality of first openings for exposing the first conductive pads and a plurality of second openings for exposing the second conductive pads; a conductive layer formed on the first conductive pads, the second conductive pads and the first insulating layer around peripheries of the first and second conductive pads; a plurality of conductive bumps formed on the conductive layer on the second conductive pads; a solder layer formed on the conductive bumps; and a plurality of conductive posts formed on the conductive layer on the first conductive pads.

The present invention further provides a fabrication method of a packaging substrate, which comprises the steps of: providing a substrate body having a first surface with a plurality of first conductive pads and a plurality of second conductive pads and a second surface opposite to the first surface; forming on the first surface of the substrate body a first insulating layer having a plurality of first openings for exposing the first conductive pads and a plurality of second openings for exposing the second conductive pads; forming a conductive layer on the first insulating layer, the first conductive pads and the second conductive pads; forming on the conductive layer a first resist layer having a plurality of fourth openings for exposing the first openings of the first insulating layer and a plurality of fifth openings for exposing the second openings of the first insulating layer; forming a plurality of first conductive bumps in the fourth openings and a plurality of second conductive bumps in the fifth openings by electroplating; forming a solder layer on the first conductive bumps and the second conductive bumps; forming a second resist layer on the first resist layer and the solder layer, wherein the second resist layer has a plurality of sixth openings corresponding in position to the first conductive bumps; removing the solder layer on the first conductive bumps; forming a plurality of conductive posts on the first conductive bumps; and removing the second resist layer, the first resist layer and the conductive layer covered by the first and second resist layers.

The present invention further provides another fabrication method of a packaging substrate, which comprises the steps of: providing a substrate body having a first surface with a plurality of first conductive pads and a plurality of second conductive pads and a second surface opposite to the first surface; forming on the first surface of the substrate body a first insulating layer having a plurality of first openings for exposing the first conductive pads and a plurality of second openings for exposing the second conductive pads; forming a conductive layer on the first insulating layer, the first conductive pads and the second conductive pads; forming on the conductive layer a first resist layer having a plurality of fourth openings for exposing the second openings of the first insulating layer; forming a plurality of conductive bumps in the fourth openings by electroplating; forming a solder layer on the conductive bumps; removing the first resist layer; forming a second resist layer on the conductive layer, the conductive bumps and the solder layer, wherein the second resist layer has a plurality of fifth openings corresponding in position to the first openings of the first insulating layer; forming a plurality of conductive posts on the conductive layer in the fifth openings of the second resist layer; and removing the second resist layer and the conductive layer covered by the second resist layer.

Therefore, by reducing the number of times to perform the patterning and removing processes of the resist layers for forming the conductive bumps and the conductive posts, the present invention simplifies the fabrication process and reduces the fabrication time and cost.

### BRIEF DESCRIPTION OF DRAWINGS

FIGS. 1A to 1J are schematic cross-sectional views showing a conventional packaging substrate used for a stack package structure and a fabrication method thereof;

FIGS. 2A to 2I are schematic cross-sectional views showing a packaging substrate and a fabrication method thereof according to a first embodiment of the present invention, wherein FIGS. 2F′ to 2I′ and FIGS. 2F″ to 2I″ show different embodiments of FIGS. 2F to 2I; and

FIGS. 3A to 3I are schematic cross-sectional views showing a packaging substrate and a fabrication method thereof according to a second embodiment of the present invention.

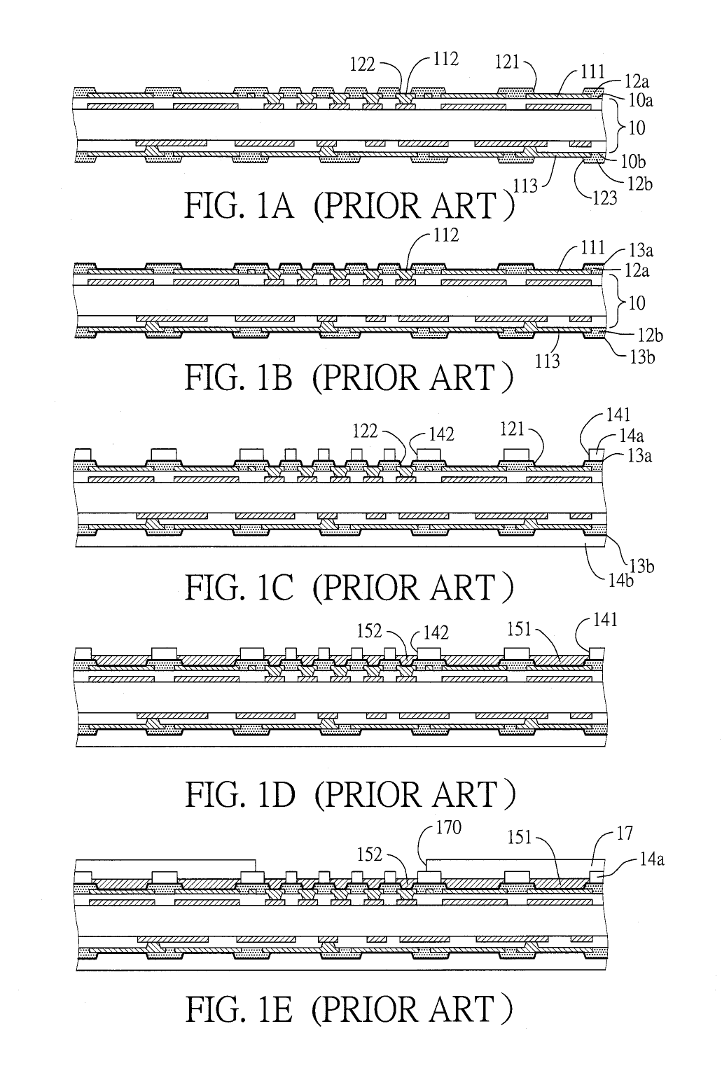

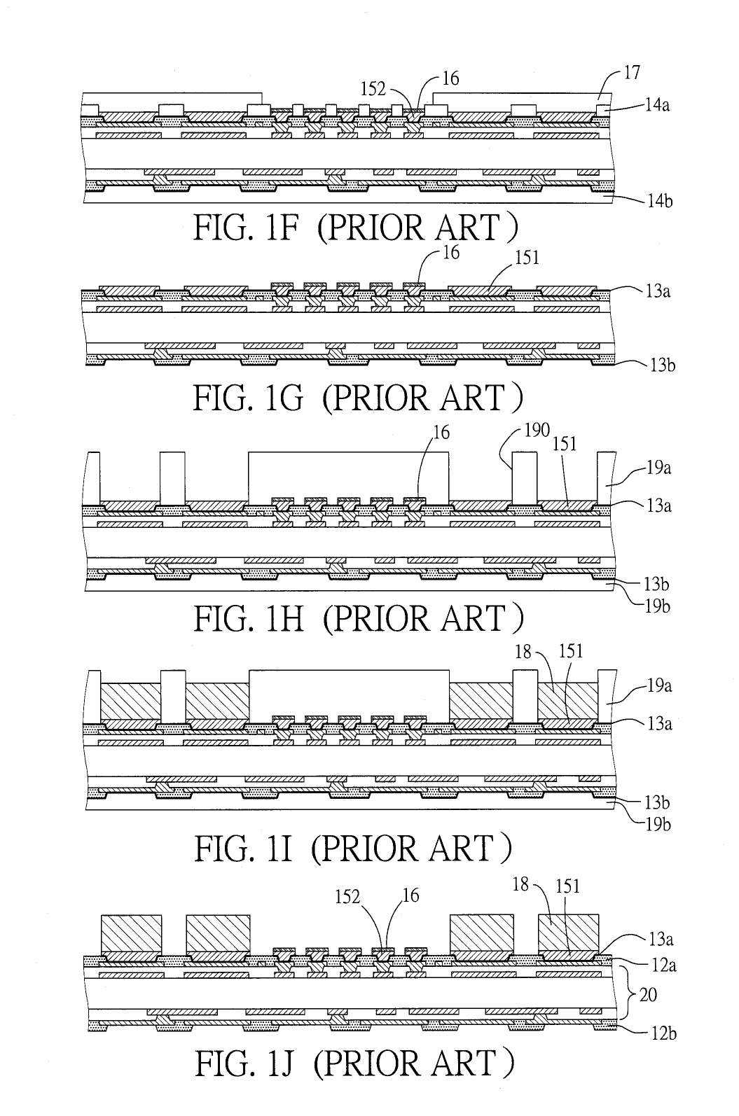

### DETAILED DESCRIPTION OF PREFERRED EMBODIMENTS

The following illustrative embodiments are provided to illustrate the disclosure of the present invention, these and other advantages and effects can be apparent to those in the art after reading this specification.

It should be noted that the drawings are only for illustrative purposes and not intended to limit the present invention. Meanwhile, terms such as “on”, “periphery” etc. are only used as a matter of descriptive convenience and not intended to have any other significance or provide limitations for the present invention.

### First Embodiment

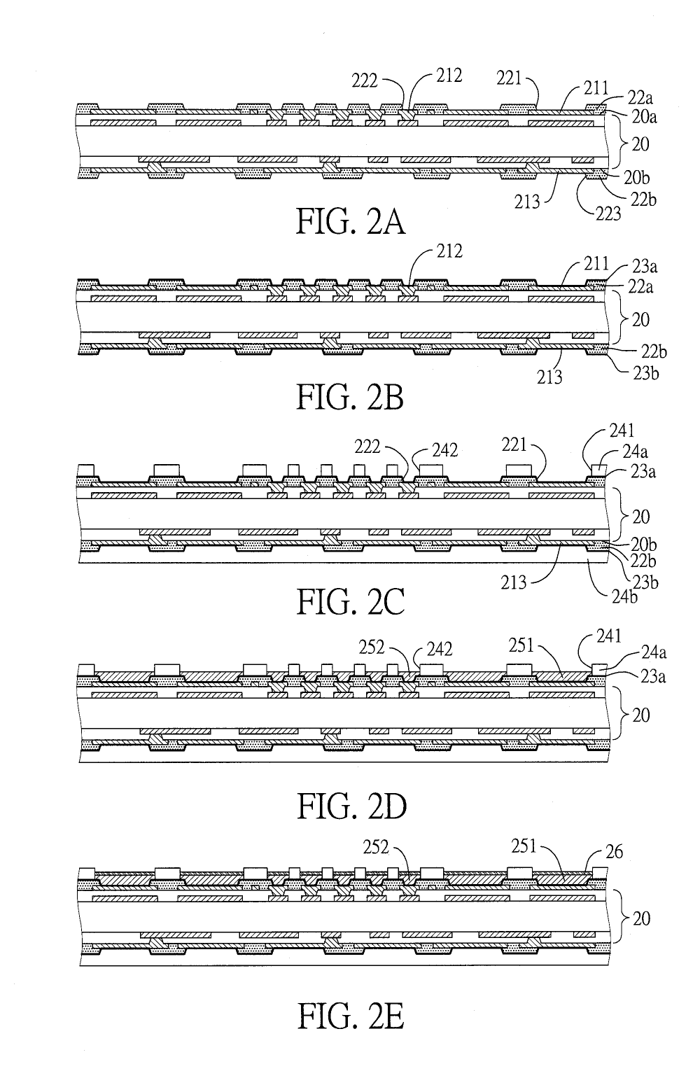

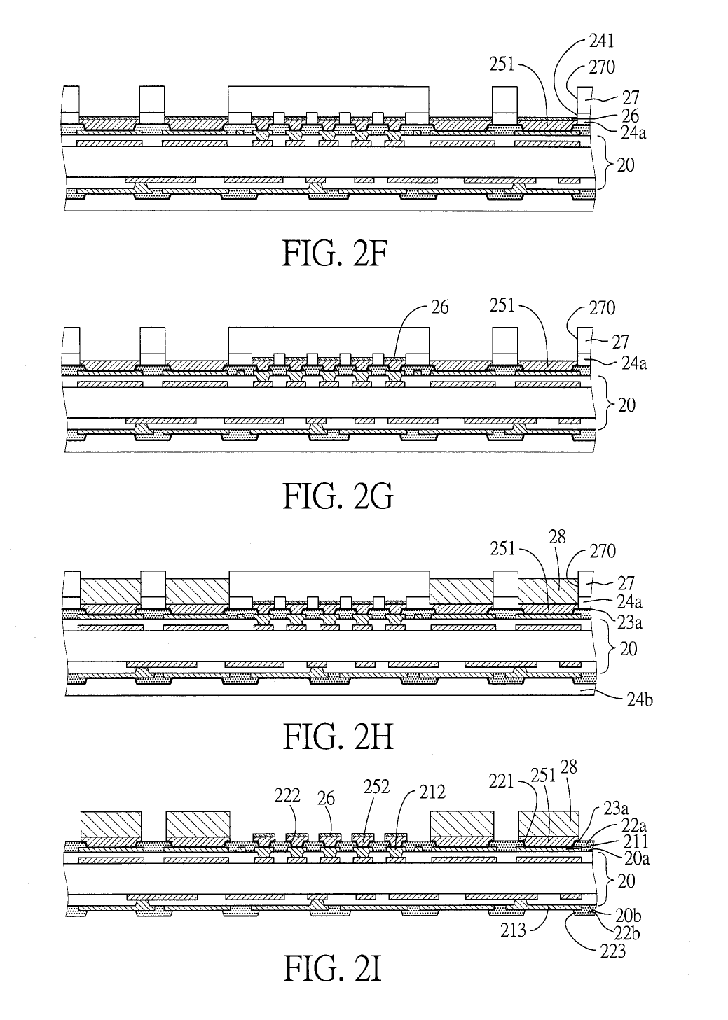

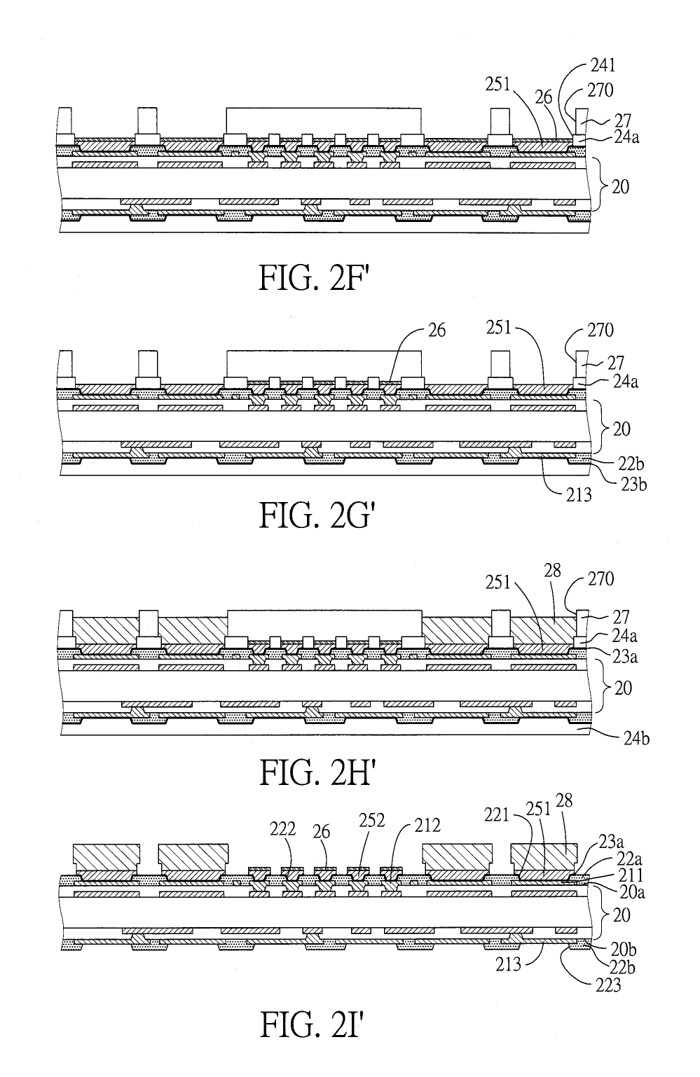

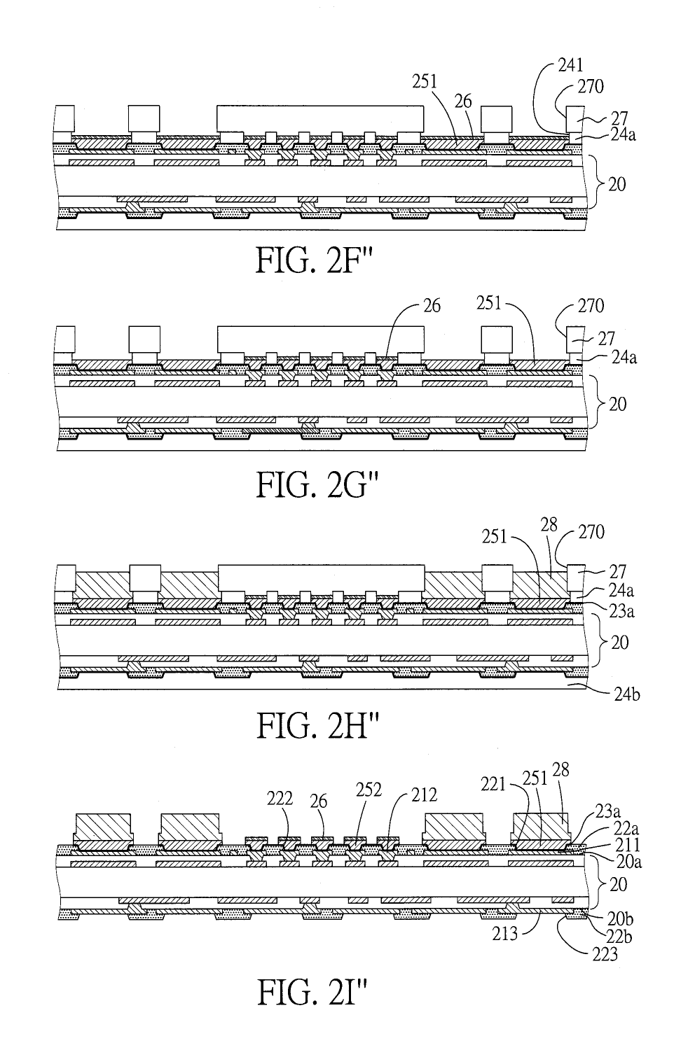

FIGS. 2A to 2I are schematic cross-sectional views showing a packaging substrate and a fabrication method thereof according to a first embodiment of the present invention. FIGS. 2F′ to 2I′ and FIGS. 2F″ to 2I″ show different embodiments of FIGS. 2F to 2I.

Referring to FIG. 2A, a substrate body 20 having a first surface 20a and a second surface 20b opposite to the first surface 20a is provided. The first surface 20a has a plurality of first conductive pads 211 and a plurality of second conductive pads 212, and the second surface 20b has a plurality of third conductive pads 213. A first insulating layer 22a is formed on the first surface 20a of the substrate body 20 and has a plurality of first openings 221 for exposing the first conductive pads 211 and a plurality of second openings 222 for exposing the second conductive pads 212. A second insulating layer 22b is formed on the second surface 20b of the substrate body 20 and has a plurality of third openings 223 for exposing the third conductive pads 213. The substrate body 20 can be a core layer, a multi-layer board having a core layer, a coreless single-layer board or a coreless multi-layer board.

Referring to FIG. 2B, a first conductive layer 23a is formed on the first insulating layer 22a and the first and second conductive pads 211, 212, and a second conductive layer 23b is formed on the second insulating layer 22b and the third conductive pads 213.

Referring to FIG. 2C, a first resist layer 24a is formed on the first conductive layer 23a and has a plurality of fourth openings 241 for exposing the first openings 221 of the first insulating layer 22a and a plurality of fifth openings 242 for exposing the second openings 222 of the first insulating layer 22a, and a third resist layer 24b is formed on the second conductive layer 23b.

Referring to FIG. 2D, a plurality of first conductive bumps 251 are formed in the fourth openings 241 and a plurality of second conductive bumps 252 are formed in the fifth openings 242. The first conductive bumps 251 and the second conductive bumps 252 can be made of copper.

Referring to FIG. 2E, a solder layer 26 is formed on the first conductive bumps 251 and the second bumps 252.

Referring to FIG. 2F, a second resist layer 27 is formed on the first resist layer 24a and the solder layer 26 and has a plurality of sixth openings 270 corresponding in position to the first conductive bumps 251. The sixth openings 270 are equal in projective width to the fourth openings 241.

Referring to FIG. 2G, the solder layer 26 on the first conductive bumps 251 is removed.

Referring to FIG. 2H, a plurality of conductive posts 28 are formed on the first conductive bumps 251. The conductive posts 28 can be made of copper.

Referring to FIG. 2I, the second resist layer 27, the first resist layer 24a and the first conductive layer 23a covered by the first and second resist layers 24a, 27 are removed, and the third resist layer 24b and the second conductive layer 23b covered by the third resist layer 24b are removed.

FIGS. 2F′ to 2I′ and FIGS. 2F″ to 2I″ show different embodiments of FIGS. 2F to 2I. Referring to FIGS. 2F′ to 2I′, the sixth openings 270 of the second resist layer 27 can be greater in projective width than the fourth openings 241 of the first resist layer 24. Referring to FIGS. 2F″ to 2I″, the sixth openings 270 of the second resist layer 27 can be less in projective width than the fourth openings 241 of the first resist layer 24.

### Second Embodiment

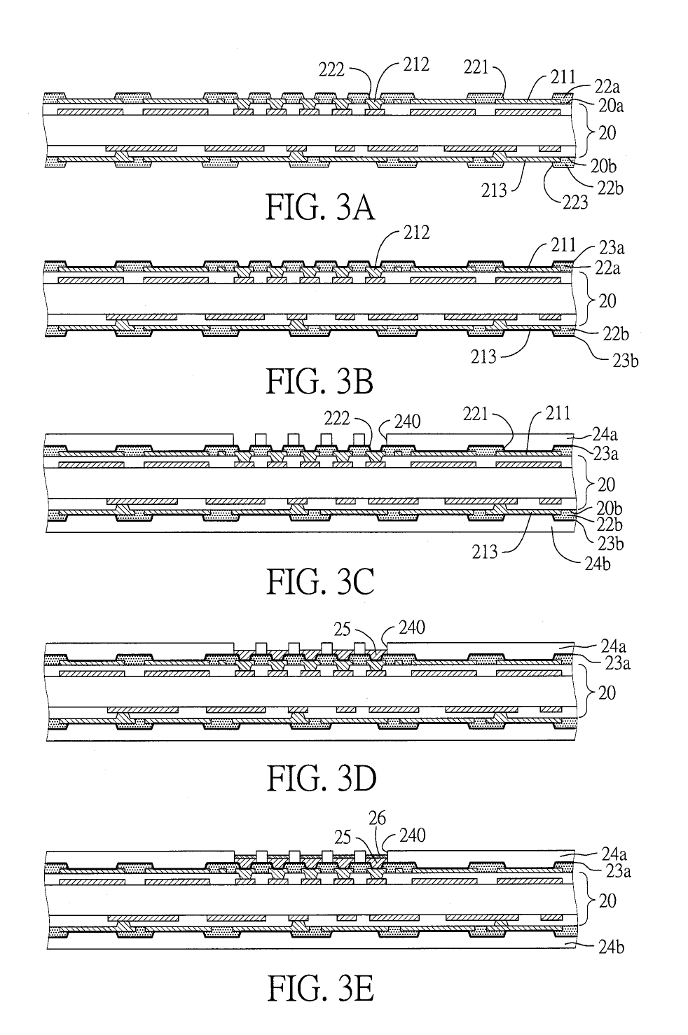

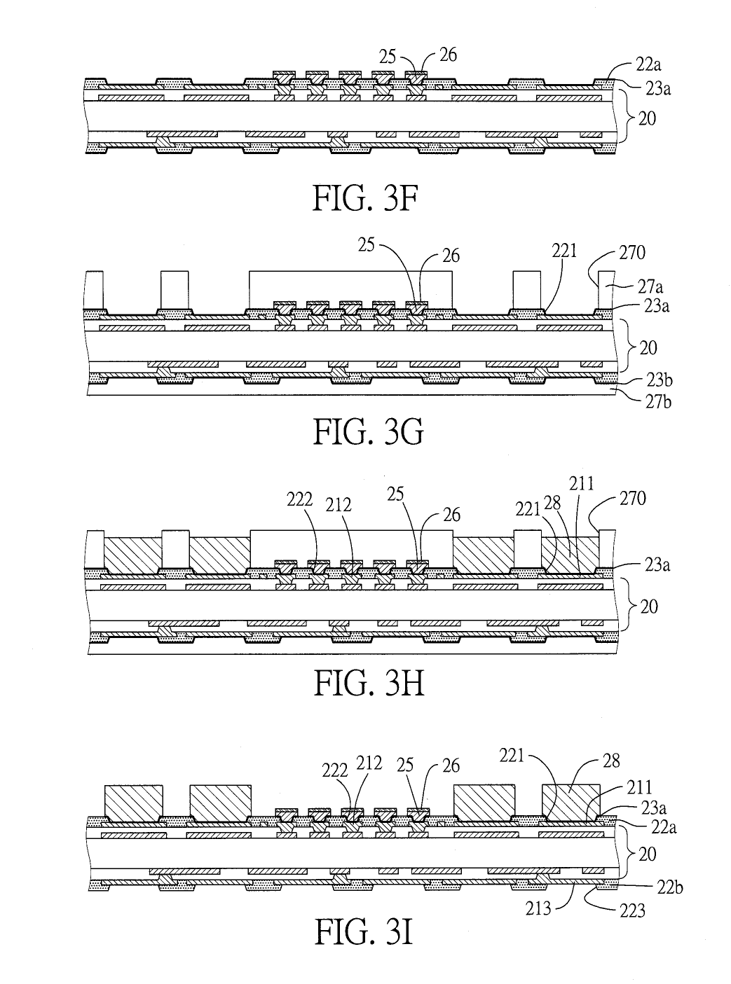

FIGS. 3A to 3I are schematic cross-sectional views showing a packaging substrate and a fabrication method thereof according to a second embodiment of the present invention.

Referring to FIG. 3A, a substrate body 20 having a first surface 20a and a second surface 20b opposite to the first surface 20a is provided. The first surface 20a has a plurality of first conductive pads 211 and a plurality of second conductive pads 212, and the second surface 20b has a plurality of third conductive pads 213. A first insulating layer 22a is formed on the first surface 20a of the substrate body 20 and has a plurality of first openings 221 for exposing the first conductive pads 211 and a plurality of second openings 222 for exposing the second conductive pads 212. A second insulating layer 22b is formed on the second surface 20b of the substrate body 20 and has a plurality of third openings 223 for exposing the third conductive pads 213. The substrate body 20 can be a core layer, a multi-layer board having a core layer, a coreless single-layer board or a coreless multi-layer board.

Referring to FIG. 3B, a first conductive layer 23a is formed on the first insulating layer 22a and the first and second conductive pads 211, 212, and a second conductive layer 23b is formed on the second insulating layer 22b and the third conductive pads 213.

Referring to FIG. 3C, a first resist layer 24a is formed on the first conductive layer 23a and has a plurality of fourth openings 240 for exposing the second openings 222 of the first insulating layer 22a, and a third resist layer 24b is formed on the second conductive layer 23b.

Referring to FIG. 3D, a plurality of conductive bumps 25 are formed in the fourth openings 240. The conductive bumps 25 can be made of copper.

Referring to FIG. 3E, a solder layer 26 is formed on the conductive bumps 25.

Referring to FIG. 3F, the first resist layer 24a and the third resist layer 24b are removed.

Referring to FIG. 3G, a second resist layer 27a is formed on the first conductive layer 23a, the conductive bumps 25 and the solder layer 26 and has a plurality of fifth openings 271 corresponding in position to the first openings 221, and a fourth resist layer 27b is formed on the second conductive layer 23b.

Referring to FIG. 3H, a plurality of conductive posts 28 are formed on the first conductive layer 23a in the fifth openings 271 of the second resist layer 27a. The conductive posts 28 can be made of copper.

Referring to FIG. 3I, the second resist layer 27 and the first conductive layer 23a covered by the first resist layers 27 are removed, and the fourth resist layer 27b and the second conductive layer 23b covered by the fourth resist layer 27b are removed.

The present invention further provides a packaging substrate, which has: a substrate body 20 having a first surface 20a with a plurality of first conductive pads 211 and a plurality of second conductive pads 212 and a second surface 20b opposite to the first surface 20a; a first insulating layer 22a formed on the first surface 20a and having a plurality of first openings 221 for exposing the first conductive pads 211 and a plurality of second openings 222 for exposing the second conductive pads 212; a first conductive layer 23a formed on the first conductive pads 211, the second conductive pads 212 and the first insulating layer 22a around peripheries of the first and second conductive pads 211, 212; a plurality of first conductive bumps 251 formed on the first conductive layer 23a on the first conductive pads 211 and a plurality of second conductive bumps 252 formed on the first conductive layer 23a on the second conductive pads 212; a solder layer 26 formed on the second conductive bumps 252; and a plurality of conductive posts 28 formed on the first conductive bumps 251 and having a width different from that of the first conductive bumps 251.

In the above-described packaging substrate, the width of the conductive posts 28 is greater or less than that of the first conductive bumps 251.

In the above-described packaging substrate, the second surface 20b of the substrate body 20 further has a plurality of third conductive pads 213 and a second insulating layer 22b is formed on the second surface 20b and has a plurality of third openings 223 for exposing the third conductive pads 213.

In the above-described packaging substrate, the substrate body 20 can be a core layer, a multi-layer board having a core layer, a coreless single-layer board or a coreless multi-layer board. The first conductive bumps 251, the second conductive bumps 252 and the conductive posts 28 can be made of copper.

The present invention further provides another packaging substrate, which has: a substrate body 20 having a first surface 20a with a plurality of first conductive pads 211 and a plurality of second conductive pads 212 and a second surface 20b opposite to the first surface 20a; a first insulating layer 22a formed on the first surface 20a and having a plurality of first openings 221 for exposing the first conductive pads 211 and a plurality of second openings 222 for exposing the second conductive pads 212; a first conductive layer 23a formed on the first conductive pads 211, the second conductive pads 212 and the first insulating layer 22a around peripheries of the first and second conductive pads 211, 212; a plurality of conductive bumps 25 formed on the first conductive layer 23a on the second conductive pads 212; a solder layer 26 formed on the conductive bumps 25; and a plurality of conductive posts 28 formed on the first conductive layer 23a on the first conductive pads 211.

In the above-described packaging substrate, the substrate body 20 can be a core layer, a multi-layer board having a core layer, a coreless single-layer board or a coreless multi-layer board.

In the above-described packaging substrate, the second surface 20b of the substrate body 20 further has a plurality of third conductive pads 213 and a second insulating layer 22b is formed on the second surface 20b and has a plurality of third openings 223 exposing the third conductive pads 213.

In the above-described packaging substrate, the conductive bump 25 and the conductive posts 28 can be made of copper.

Therefore, by reducing the number of times to perform the patterning and removing processes of the resist layers for forming the conductive bumps and the conductive posts, the present invention simplifies the fabrication process and reduces the fabrication time and cost.

The above-described descriptions of the detailed embodiments are only to illustrate the preferred implementation according to the present invention, and it is not to limit the scope of the present invention. Accordingly, all modifications and variations completed by those with ordinary skill in the art should fall within the scope of present invention defined by the appended claims.

What is claimed is:

1. A packaging substrate, comprising:
a substrate body having a first surface with a plurality of first conductive pads and a plurality of second conductive pads and a second surface opposite to the first surface;
a first insulating layer formed on the first surface of the substrate body and having a plurality of first openings for exposing the first conductive pads and a plurality of second openings for exposing the second conductive pads;
a conductive layer formed on the first conductive pads, the second conductive pads and the first insulating layer around peripheries of the first and second conductive pads;
a plurality of first conductive bumps formed on the conductive layer on the first conductive pads and a plurality of second conductive bumps formed on the conductive layer on the second conductive pads;
a solder layer formed on the second conductive bumps; and
a plurality of conductive posts formed on the first conductive bumps and having a width different from that of the first conductive bumps.

2. The substrate of claim 1, wherein the width of the conductive posts is greater than that of the first conductive bumps.

3. The substrate of claim 1, wherein the width of the conductive posts is less than that of the first conductive bumps.

4. The substrate of claim 1, wherein the substrate body is a core layer, a multi-layer board having a core layer, a coreless single-layer board or a coreless multi-layer board.

5. The substrate of claim 1, wherein the second surface of the substrate body further has a plurality of third conductive pads, and the substrate further comprises a second insulating layer formed on the second surface of the substrate body and having a plurality of third openings for exposing the third conductive pads.

6. The substrate of claim 1, wherein the first conductive bumps, the second conductive bumps and the conductive posts are made of copper.

7. A packaging substrate, comprising:
a substrate body having a first surface with a plurality of first conductive pads and a plurality of second conductive pads and a second surface opposite to the first surface;
a first insulating layer formed on the first surface of the substrate body and having a plurality of first openings for exposing the first conductive pads and a plurality of second openings for exposing the second conductive pads;
a conductive layer formed on the first conductive pads, the second conductive pads and the first insulating layer around peripheries of the first and second conductive pads;
a plurality of conductive bumps formed on the conductive layer on the second conductive pads;
a solder layer formed on the conductive bumps; and
a plurality of conductive posts formed on the conductive layer on the first conductive pads.

8. The substrate of claim 7, wherein the substrate body is a core layer, a multi-layer board having a core layer, a coreless single-layer board or a coreless multi-layer board.

9. The substrate of claim 7, wherein the second surface of the substrate body further has a plurality of third conductive pads, and the substrate further comprises a second insulating layer formed on the second surface of the substrate body and having a plurality of third openings for exposing the third conductive pads.

10. The substrate of claim 7, wherein the conductive bumps and the conductive posts are made of copper.

11. A fabrication method of a packaging substrate, comprising the steps of:
providing a substrate body having a first surface with a plurality of first conductive pads and a plurality of second conductive pads and a second surface opposite to the first surface;
forming on the first surface of the substrate body a first insulating layer having a plurality of first openings for exposing the first conductive pads and a plurality of second openings for exposing the second conductive pads;
forming a conductive layer on the first insulating layer, the first conductive pads and the second conductive pads;
forming on the conductive layer a first resist layer having a plurality of fourth openings for exposing the first openings of the first insulating layer and a plurality of fifth openings for exposing the second openings of the first insulating layer;
forming a plurality of first conductive bumps in the fourth openings and a plurality of second conductive bumps in the fifth openings by electroplating;
forming a solder layer on the first conductive bumps and the second conductive bumps;
forming a second resist layer on the first resist layer and the solder layer, wherein the second resist layer has a plurality of sixth openings corresponding in position to the first conductive bumps;
removing the solder layer on the first conductive bumps;
forming a plurality of conductive posts on the first conductive bumps; and
removing the second resist layer, the first resist layer and the conductive layer covered by the first and second resist layers.

12. The method of claim 11, wherein the sixth openings of the second resist layer are greater in projective width than, equal in projective width to or less in projective width than the fourth openings of the first resist layer.

13. The method of claim 11, wherein the substrate body is a core layer, a multi-layer board having a core layer, a coreless single-layer board or a coreless multi-layer board.

14. The method of claim 11, wherein the second surface of the substrate body further has a plurality of third conductive pads, and the method further comprises forming on the second surface of the substrate body a second insulating layer having a plurality of third openings for exposing the third conductive pads.

15. The method of claim 11, wherein the first conductive bumps, the second conductive bumps and the conductive posts are made of copper.

16. A fabrication method of a packaging substrate, comprising the steps of:
providing a substrate body having a first surface with a plurality of first conductive pads and a plurality of second conductive pads and a second surface opposite to the first surface;
forming on the first surface of the substrate body a first insulating layer having a plurality of first openings for exposing the first conductive pads and a plurality of second openings for exposing the second conductive pads;
forming a conductive layer on the first insulating layer, the first conductive pads and the second conductive pads;
forming on the conductive layer a first resist layer having a plurality of fourth openings for exposing the second openings of the first insulating layer;
forming a plurality of conductive bumps in the fourth openings by electroplating;
forming a solder layer on the conductive bumps;
removing the first resist layer;
forming a second resist layer on the conductive layer, the conductive bumps and the solder layer, wherein the second resist layer has a plurality of fifth openings corresponding in position to the first openings of the first insulating layer;
forming a plurality of conductive posts on the conductive layer in the fifth openings of the second resist layer; and
removing the second resist layer and the conductive layer covered by the second resist layer.

17. The method of claim 16, wherein the substrate body is a core layer, a multi-layer board having a core layer, a coreless single-layer board or a coreless multi-layer board.

18. The method of claim 16, wherein the second surface of the substrate body further has a plurality of third conductive pads, and the method further comprises forming on the second surface of the substrate body a second insulating layer having a plurality of third openings for exposing the third conductive pads.

19. The method of claim 16, wherein the conductive bumps and the conductive posts are made of copper.
